(19) United States
(12) Patent Application Publication
(10) Pub. No.: US 2026/0265904 A1
(43) Pub. Date: Sep. 10, 2026

(54) METHOD FOR SELECTIVELY MODIFYING SUBSTRATE SURFACE AND COMPOSITION

(71) Applicant: JSR CORPORATION, Tokyo (JP)

(72) Inventors: Soichiro AKAGI, Hsinchu County (TW); Han-Ching LIN, Hsinchu County (TW); Kosuke Mori, Hsinchu County (TW); Xin-Chun HUANG, Hsinchu County (TW); Shuhei NAKAMURA, Hsinchu County (TW)

(73) Assignee: JSR CORPORATION, Tokyo (JP)

(21) Appl. No.: 19/165,599

(22) PCT Filed: Dec. 25, 2023
(86) PCT No.: PCT/JP2023/046511

§ 371 Date: Sep. 16, 2025

(30) Foreign Application Priority Data
Mar. 29, 2023 (JP) 2023-053728

(51) Int. Cl. C23C 16/04; C09D 5/16; C09D 7/20; C09D 7/61; C09D 7/63; C23C 16/06; C23C 16/455

(52) U.S. Cl. CPC C23C 16/04; C09D 5/1625; C09D 7/20; C09D 7/61; C09D 7/63; C23C 16/06; C23C 16/45525

(57) ABSTRACT

This method for selectively modifying a substrate surface comprises a step for coating a composition onto the surface of the substrate. The composition contains water and a compound (A) having a carboxylate anion component and a monovalent organic group with 8 carbon atoms or more.

### CROSS-REFERENCE TO RELATED APPLICATIONS

The application claims priority based on Japanese Patent Application No. 2023-53728 filed on Mar. 29, 2023, the entirety of which is incorporated herein by reference.

### TECHNICAL FIELD

The disclosure relates to a method for selectively modifying a substrate surface, a method for manufacturing a surface-treated substrate, and a composition.

### RELATED ART

In semiconductor manufacturing processes, in order to cover and protect a partial region on a substrate surface, an organic film is formed in the partial region, and various treatments such as formation of a metal layer and etching are performed on the substrate after the organic film formation. In the case of forming an organic film on a substrate surface for protecting a partial region of the substrate surface, it is required to be capable of forming a film with high selectivity to a region to be protected on the substrate surface, along with further miniaturization of semiconductor devices (for example, see Patent Document 1).

Patent Document 1 discloses that a composition containing a first polymer having a group containing a first functional group that bonds with a metal contained in a first region at a terminal of a main chain or side chain, and a solvent is coated to a surface of a substrate having a first region containing metal on a surface layer, and a coating film formed by the coating of the composition is heated, thereby selectively surface-modifying the first region with the first polymer. Patent Document 1 also discloses using solvents capable of dissolving or dispersing the first polymer, such as alcohol-based solvents, ether-based solvents, ketone-based solvents, amide-based solvents, and hydrocarbon-based solvents, as solvents used for preparing the composition.

### PRIOR ART DOCUMENTS

### Patent Documents

Patent Document 1: International Publication No. WO 2018/043304

### SUMMARY OF INVENTION

### Issues to be Solved by the Invention

In a composition used for selective modification of a substrate surface, if water can be used as the main component of the solvent, it is expected that environmental burden can be reduced and the handleability of the composition can be improved. However, in compositions containing water, the precipitation of components contained in the composition tends to occur easily, and the storage stability of the composition tends to decrease. Particularly, in the case of imparting water repellency to a substrate surface by selective modification of the substrate surface, a material with high hydrophobicity is used as the film forming material. Therefore, there is a concern that the storage stability of the composition tends to decrease due to insufficient solubility of the film forming material in water.

Also, from the viewpoint of stabilizing product quality in semiconductor manufacturing processes and suppressing the decrease in product yield, at the time of protecting a portion of the region on a substrate surface, it is required to selectively protect the region to be protected. Furthermore, it is required to modify the region to be protected with high density, so that it is difficult for impurities to adhere to the protected region (that is, having high blocking performance).

The disclosure has been made in view of the above issues, and has as a main object to provide a method for selectively modifying a substrate surface and a composition that have high storage stability of the composition used for selective modification of the substrate surface, and moreover can modify the substrate surface with high selectivity and high density.

### Means for Solving the Issues

To solve the above issues, the disclosure provides means as follows.
[1] A method for selectively modifying a substrate surface includes: a process of coating a composition onto a surface of a substrate. The composition includes: Compound (A) having a carboxylate anion component and a monovalent organic group having 8 carbon atoms or more; and water.
[2] A method for manufacturing a surface-treated substrate includes: a process of coating a composition on a surface of a substrate to selectively modify the surface of the substrate. The composition includes: Compound (A) having a carboxylate anion component and a monovalent organic group having 8 carbon atoms or more; and water.
[3] A composition for selectively modifying a substrate surface includes: Compound (A), having a carboxylate anion component and a monovalent organic group having 8 carbon atoms or more; and water.

### Effects of Invention

According to the disclosure, the storage stability of the composition used for selective modification of a substrate surface is high, and moreover the substrate surface can be modified with high selectivity and high density.

### DESCRIPTION OF EMBODIMENTS

Hereinafter, matters related to the embodiments will be described in detail. In the specification, numerical ranges described using “~” mean that the numerical values described before and after “~” are included as lower limit values and upper limit values. Unless otherwise specified, each component may be used alone or in combination of two or more types.

### <<Method for Selectively Modifying a Substrate Surface and Composition>>

The method for selectively modifying a substrate surface of the disclosure (hereinafter also simply referred to as “selective modification method”) includes a process of coating a composition (hereinafter also referred to as “surface modification composition”) to a surface of a substrate. The surface modification composition is an aqueous liquid composition and contains Compound (A) having a carboxylate anion component and a monovalent organic group having 8 or more carbon atoms, and water as a solvent component. Hereinafter, the surface modification composition will be described first, followed by the description of the method for selectively modifying a substrate surface by using the surface modification composition.

### <Surface Modification Composition>

The surface modification composition is used as a surface treatment solution for forming a film on a substrate surface to perform surface modification of the substrate. Water repellency is imparted to the region where the film is formed by the surface modification composition. The film formed by the surface modification composition is typically a self-assembled monolayer (SAM) formed by adsorption of Compound (A) to the substrate surface. Hereinafter, each component contained in the surface modification composition and components optionally blended as necessary (hereinafter also referred to as “other components”) will be described.

### Compound (A)

Compound (A) has a carboxylate anion component and a monovalent organic group having 8 or more carbon atoms (hereinafter also referred to as “monovalent organic group R¹”). By using Compound (A) as a monomolecular film forming material, the adsorption ability to a substrate (particularly a metal region) is exhibited by the carboxylate anion component, and water repellency is exhibited by the monovalent organic group R¹. This enables imparting excellent water repellency to the substrate surface. In particular, Compound (A), by having a carboxylate anion component, can enhance the water solubility of Compound (A) while highly selectively and densely modifying metal region of the substrate through the interaction with metals. The “interaction” here refers to, for example, a chemical bond, including covalent bonds, ionic bonds, coordinate bonds, and the like. In the case of the carboxylate anion component forming coordinate bonds with metals, it is possible to enhance the bonding force between metal atoms and carboxylate anions.

Compound (A) is a compound (low molecular weight compound) different from polymers. The molecular weight of Compound (A) is preferably 1,000 or less, more preferably 800 or less, still more preferably 700 or less, and even more preferably 600 or less from the viewpoint of ensuring solubility in water. Further, from the viewpoint of obtaining a film with good heat resistance, the molecular weight of Compound (A) is preferably 155 or more, more preferably 180 or more, and still more preferably 200 or more.

Compound (A) may have one or more carboxylate anion components, and the number thereof is not particularly limited. From the viewpoint of enhancing adsorption to the substrate (particularly metal regions), Compound (A) preferably has two or more carboxylate anion moieties. Further, to ensure adsorption to the substrate, the number of carboxylate anion components that Compound (A) has is preferably 6 or less, more preferably 4 or less.

The carboxylate anion component that Compound (A) has may form a salt with basic cations such as ammonium ions. In the case of the carboxylate anion component forming a salt, the counter ion may be any cationic counter ion.

Specific examples of cations that form salts with the carboxylate anion component include metal ions such as lithium ion, sodium ion, potassium ion, rubidium ion, cesium ion, magnesium ion, calcium ion, strontium ion, and barium ion; organic cations such as ammonium ion, 2-ethanolammonium ion, 1-butanol-4-ammonium ion, diethanolammonium ion, triethanolammonium ion, propylammonium ion, butylammonium ion, diisopropylammonium ion, dibutylammonium ion, ethylenediammonium ion, 2,2-imidodi(ethylammonium ion), N,N′-di(2-ammoniumethyl)ethylenediammonium ion, N,N-bis(2-aminoethyl)methylammonium ion, N,N-bis(3-aminopropyl)methylammonium ion, tetramethylammonium ion, tetraethylammonium ion, and tetrabutylammonium ion.

From the viewpoint of enhancing adsorption to metal regions, the carboxylate anion component that Compound (A) has preferably forms a carboxy group with a hydrogen ion, or forms a salt with an organic cation.

The carboxylate anion component that Compound (A) has may be bonded to an aliphatic carbon or may be bonded to an aromatic carbon. From the viewpoint of improving the solubility in an aqueous solution and the storage stability, at least a portion of the carboxylate anion components that Compound (A) has is preferably bonded to an aliphatic carbon, and it is preferable that all of the carboxylate anion components that Compound (A) has are bonded to aliphatic carbons. In the case where Compound (A) has two or more carboxylate anion components, Compound (A) preferably has a structure in which two or more carboxylate anion components are bonded to a chain hydrocarbon group, and more preferably has a structure in which two or more carboxylate anion components are bonded to a saturated chain hydrocarbon. The chain hydrocarbon to which the carboxylate anion components are bonded may be linear or branched.

Examples of a monovalent organic group R¹ that Compound (A) has include a monovalent hydrocarbon group, a monovalent group in which any hydrogen atom of the monovalent hydrocarbon group is substituted with a halogen atom (fluorine atom, chlorine atom, bromine atom, iodine atom, etc.), a phosphonyl group, a sulfonyl group, an acetyl group, or a formyl group. From the viewpoint of causing the film formed by the surface modification composition to exhibit excellent water repellency, the monovalent organic group R¹ preferably does not have carboxylate ion (—COO⁻).

From the viewpoint of obtaining a film with excellent water repellency by coating the surface modification composition on a substrate surface, the monovalent organic group R¹ is preferably a monovalent hydrocarbon group or a halogenated hydrocarbon group having 8 or more carbon atoms. The carbon number of the monovalent organic group R¹ is, for example, 8 to 40 carbon atoms.

Here, in the present specification, “hydrocarbon group” means to include chain hydrocarbon group, alicyclic hydrocarbon group, and aromatic hydrocarbon group. “Chain hydrocarbon group” means linear a hydrocarbon group and a branched hydrocarbon group that do not contain a cyclic structure and contain only of a chain structure. The chain hydrocarbon group may be saturated or unsaturated. “Alicyclic hydrocarbon group” means a hydrocarbon group that contains only an alicyclic hydrocarbon structure as a ring structure and does not contain an aromatic ring structure. The alicyclic hydrocarbon group does not need to be formed only of an alicyclic hydrocarbon structure, and also includes those having a chain structure in a portion thereof. “Aromatic hydrocarbon group” means a hydrocarbon group that contains an aromatic ring structure as a ring structure. However, it does not need to be formed only of an aromatic ring structure, and may contain a chain structure or an alicyclic hydrocarbon structure in a portion thereof.

As specific examples of the monovalent organic group R¹, examples of the monovalent hydrocarbon group include a monovalent chain hydrocarbon group having 8 to 40 carbon atoms, a monovalent alicyclic hydrocarbon group having 8 to 40 carbon atoms, and a monovalent aromatic hydrocarbon group having 8 to 40 carbon atoms.

As specific examples in the case where the organic group R¹ is a monovalent hydrocarbon group, examples of the monovalent chain hydrocarbon group having 8 to 40 carbon atoms include linear or branched alkyl groups such as an n-octyl group, an isooctyl group, a sec-octyl group, an n-nonyl group, an isononyl group, a sec-nonyl group, an n-decyl group, an isodecyl group, a sec-decyl group, an n-undecyl group, an n-dodecyl group, an n-tridecyl group, an n-tetradecyl group, an n-pentadecyl group, an n-hexadecyl group, an n-heptadecyl group, an n-octadecyl group, an n-nonadecyl group, an n-icosyl group, an n-pentacosyl group, an n-tetracontyl group; a linear or branched alkenyl groups such as an octenyl group, a decenyl group, an isodecenyl group, a dodecenyl group, an n-hetradecenyl group, an n-hexadecenyl group, an n-octadecenyl group, an n-icosenyl group, an n-pentacosenyl group; and a linear or branched alkynyl group such as an octynyl group, a decynyl group, an isodecynyl group, a dodecynyl group, an n-hetradecynyl group, an n-hexadecynyl group, an n-octadecynyl group, an n-icosynyl group, an n-pentacosynyl group.

Examples of the monovalent alicyclic hydrocarbon group having 8 to 40 carbon atoms include monocyclic alicyclic saturated hydrocarbon groups such as a propylcyclopentyl group, a trimethylcyclopentyl group, a propylcyclohexyl group, an ethylcyclohexyl group, a dimethylcyclohexyl group, a propylcycloheptyl ethylcycloheptyl group, a methylcycloheptyl group; monocyclic alicyclic unsaturated hydrocarbon groups such as a propylcyclopentenyl group, an ethylcyclohexenyl group, a methylcycloheptenyl group, a methylcyclooctenyl group; polycyclic alicyclic saturated hydrocarbon groups such as a methylnorbornyl group, an adamantyl group, a tricyclodecyl group; and polycyclic alicyclic unsaturated hydrocarbon groups such as a methylnorbornenyl group, a tricyclodecenyl group.

Examples of the monovalent aromatic hydrocarbon group having 8 to 40 carbon atoms include aryl groups such as a dimethylphenyl group, an ethylphenyl group, a naphthyl group, an anthryl group; and aralkyl groups such as a phenethyl group, a naphthylmethyl group, an anthrylmethyl group.

As specific examples in the case where the monovalent organic group R¹ is a monovalent halogenated hydrocarbon group, examples include groups in which any hydrogen atom of the groups exemplified as the monovalent hydrocarbon group is substituted with a halogen atom (fluorine atom, chlorine atom, bromine atom, iodine atom, etc.).

From the point of improving the solubility of Compound (A) in water while being able to impart excellent water repellency to the substrate surface, the monovalent organic group R¹ is preferably a monovalent hydrocarbon group among the above, more preferably a monovalent chain hydrocarbon group, still more preferably a linear or branched alkyl group, and even more preferably a linear alkyl group. The carbon number of the monovalent organic group R¹ is preferably 8 or more, more preferably 10 or more, and still more preferably 12 or more from the viewpoint of imparting excellent water repellency to the substrate surface. Further, the carbon number of the monovalent organic group R¹ is preferably 30 or less, more preferably 20 or less, still more preferably 18 or less, and even more preferably 15 or less from the viewpoint of improving the solubility of Compound (A) in water and from the viewpoint of suppressing the decrease in the adsorption ability of Compound (A) to the substrate.

Compound (A) may have one or more carboxylate anion components and one or more monovalent organic groups R¹, respectively, and the structure thereof is not particularly limited. From the point that the coatability of the surface modification composition containing water as a solvent can be made more excellent and the point that a film of higher density can be obtained, it is preferable that Compound (A) has a carboxylate anion component that forms a carboxy group with a hydrogen ion or form a salt with organic cations, and the monovalent organic group R¹ is a hydrocarbon group or a halogenated hydrocarbon group. From the viewpoint of enabling Compound (A) to form a film of higher density, it is more preferable that Compound (A) has a carboxylate anion component that is bonded to aliphatic carbons and form a carboxy group with hydrogen ions or form salts with organic cations, and the monovalent organic group R¹ is a hydrocarbon group or a halogenated hydrocarbon group. Among these, it is preferable that Compound (A) has a carboxylate anion component that is bonded to aliphatic carbons and form salts with organic cations, and the monovalent organic group R¹ is a hydrocarbon group.

Preferable specific examples of Compound (A) may include compounds represented by Formula (0).

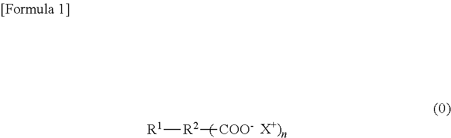

(In Formula (0), R¹ is a monovalent organic group having 8 or more carbon atoms. X⁺ is a hydrogen ion, an organic cation, or a metal cation. n is an integer of 1 or more. R² is a single bond in the case of n being 1, and is a (n+1)-valent saturated chain hydrocarbon group having 1 to 4 carbon atoms in the case of n being 2 or more.)

In Formula (0) above, R¹ is a group corresponding to the monovalent organic group R¹. Specific examples and preferable examples of the group represented by R¹ include the same groups as those described as the monovalent organic group R¹. Specific examples of the organic cation and the metal cation represented by X⁺ include the same cations as those shown above as specific examples of cations that form salts with carboxylate anion components can be raised. Among these, X⁺ is preferably a hydrogen ion or an organic cation, and more preferably an organic cation. n is preferably 1 to 6, more preferably 1 to 4, still more preferably 1 or 2, and even more preferably 2. In the case where n is 2 or more, the two or more carboxylate anion components that Compound (A) has may be bonded to the same aliphatic carbon that the saturated chain hydrocarbon group represented by R² has, or may be bonded to a different aliphatic carbon.

Further preferable specific examples of Compound (A) may include compounds represented by Formula (1) and compounds represented by Formula (2).

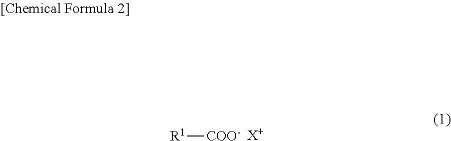

(In Formula (1), R¹ is a monovalent organic group having 8 or more carbon atoms. X⁺ is a hydrogen ion, an organic cation, or a metal cation.)

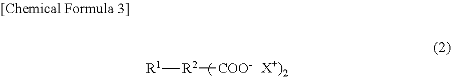

(In Formula (2), R¹ is a monovalent organic group having 8 or more carbon atoms. X⁺ is a hydrogen ion, an organic cation, or a metal cation. R² is a trivalent saturated chain hydrocarbon group having 1 to 4 carbon atoms.)

In Formula (1) and Formula (2), regarding specific examples and preferable examples of the group represented by R¹, examples may include the same groups as those described as the above monovalent organic group R¹.

Specific examples of the organic cation and metal cation represented by X⁺ include the same cations as those shown above as specific examples of cations that form salts with the carboxylate anion component. Among the above, X⁺ is preferably a hydrogen ion or an organic cation, and more preferably an organic cation.

Specific examples of Compound (A) include monocarboxylic acids such as nonanoic acid, decanoic acid, tetradecanoic acid, hexadecanoic acid, icosanoic acid, docosanoic acid, tetracosanoic acid, heptacosanoic acid, 11-mercaptoundecanoic acid, 16-mercaptohexadecanoic acid, 10-aminoundecanoic acid, 18-aminononadecanoic acid, isononanoic acid, 2-propylhexanoic acid, 3,5,5-trimethylhexanoic acid, neodecanoic acid, 2,2,3,5-tetramethylhexanoic acid, 2,4-dimethyl-2-isopropylpentanoic acid, naphthenic acid, 2,5-dimethyl-2-ethylhexanoic acid, 2,2-dimethyloctanoic acid, 2,2-diethylhexanoic acid, 1,4-dimethyl-5-(3-methyl-2-butenyl)-3-cyclohexene-1-yl-carboxylic acid, 1,3-dimethyl-2-(3-methyl-2-butenyl)-3-cyclohexene-1-yl-carboxylic acid, 1,2,3-trimethyl-5-(1-methyl-2-propenyl)-3-cyclohexene-1-yl-carboxylic acid, 1,4,5-trimethyl-2-(2-methyl-2-propenyl)-3-cyclohexene-1-yl-carboxylic acid, 1,4,5-trimethyl-2-(2-methyl-1-propenyl)-3-cyclohexene-1-yl-carboxylic acid, 1,5,6-trimethyl-3-(2-methyl-1-propenyl)-4-cyclohexene-1-yl-carboxylic acid, 1-methyl-4-(4-methyl-3-pentenyl)-4-cyclohexene-1-yl-carboxylic acid, 1-methyl-3-(4-methyl-3-pentenyl)-3-cyclohexene-1-yl-carboxylic acid, 2-methoxycarbonyl-3-(2-methyl-1-propenyl)-5,6-dimethyl-4-cyclohexene-1-yl-carboxylic acid;
dicarboxylic acids such as octylsuccinic acid, decylsuccinic acid, octadecylsuccinic acid, triacontylsuccinic acid, 1-decenylsuccinic acid, 1-octadecenylsuccinic acid, 10,10,10-trifluorodecylsuccinic acid, 18,18,18-trifluorooctadecylsuccinic acid, sodium octadecylsuccinate, potassium octadecylsuccinate, ammonium octadecylsuccinate, tetramethylammonium octadecylsuccinate, tetrabutylammonium octadecylsuccinate, ethanolamine octadecylsuccinate, triethanolamine octadecylsuccinate;
tricarboxylic acids such as 2-hydroxide-1,2,3-undecantricarboxylic acid, 2-hydroxide-1,2,3-tridecantricarboxylic acid, 2-hydroxide-1,2,3-henicosantricarboxylic acid, 2-hydroxide-1,2,3-tritriacontantricarboxylic acid, 2-hydroxide-4,5-tridecenyl-1,2,3-undecantricarboxylic acid, 2-hydroxide-4,5-eicosenyl-1,2,3-undecantricarboxylic acid, 13,13,13-trifluoro-2-hydroxide-1,2,3-tridecantricarboxylic acid, 21,21,21-trifluoro-2-hydroxide-1,2,3-henicosantricarboxylic acid, sodium 2-hydroxide-1,2,3-tridecantricarboxylate, potassium 2-hydroxide-1,2,3-tridecantricarboxylate, ammonium 2-hydroxide-1,2,3-tridecantricarboxylate, tetramethylammonium 2-hydroxide-1,2,3-tridecantricarboxylate, tetrabutylammonium 2-hydroxide-1,2,3-tridecantricarboxylate, ethanolamine 2-hydroxide-1,2,3-tridecantricarboxylate, triethanolamine 2-hydroxide-1,2,3-tridecantricarboxylate.

The content of Compound (A) in the surface modification composition is preferably 0.01% by mass or more, more preferably 0.02% by mass or more, relative to the total amount of the surface modification composition, from the viewpoint of modifying the substrate surface at high density. Further, from the viewpoint of modifying the substrate surface with high selectivity, the content of Compound (A) in the surface modification composition is preferably 1.0% by mass or less, more preferably 0.5% by mass or less, still more preferably 0.1% by mass or less, relative to the total amount of the surface modification composition.

### Solvent

The surface modification composition is an aqueous composition that contains water as a solvent component. As the solvent component of the surface modification composition, water may be used alone, but an organic solvent may be further contained. By using a mixed solvent of water and an organic solvent as the solvent components of the surface modification composition, the storage stability of the surface modification composition can be enhanced. As the organic solvent, at least one selected from the group consisting of alcohols, ethers, ketones, sulfones, amides, cyclic amines, lactams, and esters can be preferably used.

Specific examples of the organic solvent that may be blended in the surface modification composition include, as alcohols, for example, chain monoalcohols having 1 to 18 carbon atoms such as methanol, ethanol, propanol, isopropyl alcohol, 4-methyl-2-pentanol, and n-hexanol; alicyclic monoalcohols having 3 to 18 carbon atoms such as cyclohexanol; polyhydric alcohols having 2 to 18 carbon atoms such as 1,2-propylene glycol; and polyhydric alcohol partial ethers having 3 to 19 carbon atoms such as propylene glycol monomethyl ether (1-methoxy-2-propanol), 2-methoxy-1-propanol, ethylene glycol monomethyl ether, propylene glycol monomethyl ether, ethylene glycol monobutyl ether (butyl cellosolve), propylene glycol monoethyl ether, diethylene glycol monomethyl ether, diethylene glycol ethyl methyl ether, and diethylene glycol monobutyl ether.

Examples of ethers include tetrahydrofuran. Examples of ketones include acetone, methyl ethyl ketone, acetonyl acetone, and diacetone alcohol. Examples of sulfones include sulfolane and dimethyl sulfoxide. Examples of amides include cyclic amides such as N,N′-dimethylimidazolidinone and N-methylpyrrolidone; and chain amides such as N-methylformamide, N,N-dimethylformamide, N,N-diethylformamide, acetamide, N-methylacetamide, N,N-dimethylacetamide, and N-methylpropionamide. Examples of cyclic amines include morpholine and N-(3-aminopropyl) morpholine. Examples of lactams include 1-methyl-2-pyrrolidone. Examples of esters include, as chain esters, monocarboxylic acid esters such as ethyl lactate; and as cyclic esters, γ-butyrolactone and 8-valerolactone.

In the organic solvents, alcohols are preferred from the point that alcohols are easily miscible with water and can improve the coatability of the surface modification composition and the point that a film of a higher density can be formed in the case where Compound (A) is used as a film forming material. At least one selected from the group consisting of a chain monoalcohol having 1 to 18 carbon atoms, a polyhydric alcohol having 2 to 18 carbon atoms, and a polyhydric alcohol partial ether having 3 to 19 carbon atoms is more preferred, and a polyhydric alcohol partial ether having 3 to 19 carbon atoms are still more preferred. The carbon number of at least one compound selected from the group consisting of the chain monoalcohol having 1 to 18 carbon atoms, polyhydric alcohols having 2 to 18 carbon atoms, and polyhydric alcohol partial ethers having 3 to 19 carbon atoms is preferably 1 to 15, more preferably 1 to 12, and still more preferably 1 to 10.

In the case where the surface modification composition contains an organic solvent, the content of the organic solvent in the surface modification composition is preferably 70 mass % or less, more preferably 60 mass % or less, still more preferably 50 mass % or less, and even more preferably 40 mass % or less, relative to the total amount of the surface modification composition, from the viewpoints of minimizing the amount of the organic solvent used and allowing Compound (A) to form a film of a higher density. From the viewpoint of enhancing the storage stability of the surface modification composition, the content of the organic solvent in the surface modification composition is preferably 1 mass % or more, and more preferably 2 mass % or more, relative to the total amount of the surface modification composition.

The content of water in the surface modification composition is, for example, 1 mass % or more, preferably 10 mass % or more, more preferably 15 mass % or more, and still more preferably 25 mass % or more, relative to the total amount of the composition. From the viewpoint of minimizing the amount of the organic solvent used, the content of water is preferably 30 mass % or more, more preferably 35 mass % or more, still more preferably 45 mass % or more, even more preferably 55 mass % or more, further preferably 65 mass % or more, and still further preferably 70 mass % or more, relative to the total amount of water and the organic solvent contained in the surface modification composition.

### Other Components

The surface modification composition may further contain components (hereinafter also referred to as “other components”) different from Compound (A) and the solvent component, in addition to Compound (A) and the solvent component. From the viewpoint of enhancing the storage stability of the surface modification composition, the surface modification composition preferably contains a pH adjuster together with Compound (A) and water. The surface modification composition may also contain a cleaning component as such other components.

### (pH Adjuster)

The pH adjuster is a component for adjusting the hydrogen ion concentration in the surface modification composition. The pH adjuster may be any of inorganic acids, organic acids having 8 carbon atoms or less, inorganic bases, and organic bases, and may be salts thereof. A buffer solution may also be used as the pH adjuster to be blended in the surface modification composition.

Specific examples of the pH adjuster include: as inorganic acids, phosphoric acid, sulfuric acid, nitric acid, boric acid, hydrochloric acid, and the like; as organic acids having 8 carbon atoms or less, acetic acid, lactic acid, malonic acid, oxalic acid, succinic acid, citric acid, gluconic acid, maleic acid, N-propylpiperazine-N′-ethanesulfonic acid, and the like; as inorganic bases, ammonia, potassium hydroxide, sodium hydroxide, and the like; as organic bases, monoethanolamine, diethanolamine, triethanolamine, trimethylamine, triethylamine, propylamine, dibutylamine, tetramethylammonium hydroxide, tetraethylammonium hydroxide, tetrabutylammonium hydroxide, and the like. Examples of the salts include salts of the acids or bases shown above that exhibit a buffering effect, such as ammonium chloride, ammonium acetate, sodium citrate, and the like. Examples of the buffer solutions include a sodium phosphate buffer solution, a sodium acetate buffer solution, a sodium citrate phosphate buffer solution, a sodium tartrate buffer solution, a potassium borate buffer solution, a sodium borate buffer solution, and the like. The organic acids and organic bases as the pH adjuster preferably have 8 carbon atoms or less, more preferably 6 or less carbon atoms, and still more preferably 5 or less carbon atoms.

From the viewpoint of minimizing the metal content in the surface modification composition as much as possible, among the above, the pH adjuster is preferably an organic acid having 8 carbon atoms or less, ammonia, or an organic base, and more preferably a carboxy group-containing chain compound, a chain monoamine compound, or ammonia. The carboxy group-containing chain compound preferably has 8 carbon atoms or less, and more preferably 2 to 7 carbon atoms. The chain monoamine compound preferably has 8 carbon atoms or less, and more preferably 2 to 6 carbon atoms.

As the pH adjuster, among the above, at least one selected from the group consisting of ammonia, monoethanolamine, diethanolamine, triethanolamine, tetramethylammonium hydroxide, tetrabutylammonium hydroxide, ethylbutylammonium hydroxide, citric acid, malonic acid, maleic acid, oxalic acid, acetic acid, phosphoric acid, sulfuric acid, nitric acid, boric acid, and succinic acid can be preferably used.

In the case of blending a pH adjuster in the surface modification composition, the content of the pH adjuster in the surface modification composition may be such that the surface modification composition can be adjusted to a desired pH, and can be appropriately set according to the type of the pH adjuster used.

In the case where a carboxy group-containing compound having 8 carbon atoms or less is contained as a pH adjuster in the surface modification composition, in order to suppress deterioration of the coatability of the composition and the selective modification property for the substrate surface, the content of the carboxy group-containing compound having 8 carbon atoms or less is preferably 0.01 mass % or less, more preferably 0.008 mass % or less, and still more preferably 0.005 mass % or less, relative to the total amount of the composition.

The pH of the surface modification composition is preferably 13.0 or less from the viewpoint of suppressing corrosion of the substrate surface due to the surface modification composition (i.e., obtaining a composition with a high metal corrosion resistance) in the case where a film is formed on a metal substrate. The pH of the surface modification composition is more preferably 12.0 or less, still more preferably 11.0 or less, and even more preferably 10.0 or less. Further, the pH of the surface modification composition is preferably 6.0 or more, and more preferably 7.0 or more. In the specification, the pH of the composition is a value measured under conditions of 25° C. and 1 atm.

### (Cleaning Component)

For the purpose of removing components remaining on the substrate before a monomolecular film is formed on the substrate by using the surface modification composition (for example, residues due to dry etching for hole formation, etc.), a cleaning component may be blended in the surface modification composition. By blending the cleaning component together with Compound (A), a monomolecular film formed of Compound (A) can be formed on the substrate while removing components remaining on the substrate. This allows the step of removing components remaining on the substrate before formation of the monomolecular film and the step of forming the monomolecular film to be carried out in one step, which is suitable in that simplification of the process in the semiconductor manufacturing process can be achieved.

From the viewpoint of sufficiently obtaining a cleaning effect on the substrate surface while forming a high-density film on the substrate with Compound (A), the molecular weight of the cleaning component is preferably smaller than the molecular weight of Compound (A). Specifically, the molecular weight of the cleaning component is preferably 300 or less, more preferably 200 or less, still more preferably 100 or less, and even more preferably 80 or less. Further, the molecular weight of the cleaning component is preferably 10 or more, and more preferably 15 or more.

Examples of the cleaning component include fluorine compound, hydrogen peroxide, citric acid, ethylenediaminetetraacetic acid (EDTA), or two or more of the aforementioned. Specific examples of the fluorine compound include hydrofluoric acid (hydrogen fluoride), ammonium fluoride, tetramethylammonium fluoride, hexafluorosilicic acid, and the like. From the point of a high cleaning effect, a fluorine compound can be preferably used as the cleaning component.

The content of the cleaning component in the surface modification composition is preferably 0.0001 mass % or more, more preferably 0.001 mass % or more, and still more preferably 0.005 mass % or more, relative to the total amount of the surface modification composition, from the viewpoint of sufficiently obtaining a cleaning effect on the substrate. Further, from the viewpoint of not hindering the selective modification of the substrate surface by Compound (A), the content of the cleaning component is preferably 10 mass % or less, more preferably 7 mass % or less, and still more preferably 5 mass % or less, relative to the total amount of the surface modification composition.

Other components that may be blended in the surface modification composition include, in addition to the above, antioxidants and the like. The blending amounts of such other components can be appropriately selected according to each component within a range that does not affect the effects of the disclosure.

### (Metal Content)

The surface modification composition preferably has a low metal content in consideration of application to a semiconductor manufacturing process. Specifically, the total amount of sodium, potassium and calcium contained in the surface modification composition is preferably 1,000 ppm or less, more preferably less than 500 ppm, and still more preferably less than 1 ppm. The metal content in the surface modification composition is a value measured by ICP mass spectrometry (ICP-MS).

The surface modification composition can be prepared by mixing Compound (A), water, and other components blended as necessary, and dissolving compound (A) and the like in water.

The solid content concentration of the surface modification composition (that is, the ratio of the total mass of components other than the solvent component in the surface modification composition to the total mass of the surface modification composition) is preferably 0.04 mass % to 1.50 mass %, and more preferably 0.08 mass % to 1.00 mass %, from the viewpoint of forming a high-density film while ensuring good coatability and securing ALD resistance.

### <Method for Selectively Modifying Substrate Surface>

Next, the method for selectively modifying a substrate surface implemented by using the surface modification composition will be described. The selective modification method includes a coating process of coating the surface modification composition on the surface of the substrate.

### Coating Process

### (Substrate)

As the substrate, a substrate having a first region and a second region having a different material from the first region on the surface layer can be preferably used. The first region preferably has different adsorption properties for Compound (A) from the second region due to having a different material from the second region. As an example thereof, the first region is a region having higher adsorption properties for Compound (A) than the second region. From the viewpoint of selectively and densely performing surface modification on the substrate by using Compound (A), the first region is preferably formed of a conductive material, and the second region is preferably formed of an insulating material. Further, the substrate to be selectively modified by the surface modification composition preferably has a first region formed of a conductive material and a second region formed of an insulating material.

In the case where the first region is a region formed of a conductive material, the first region contains a metal element. As the metal element, for example, at least one is selected from the group consisting of copper, iron, zinc, cobalt, aluminum, titanium, tin, tungsten, zirconium, tantalum, germanium, molybdenum, ruthenium, gold, silver, platinum, palladium, and nickel. The metal element contained in the first region may be a simple metal, and may be an alloy (nickel-copper alloy, cobalt-nickel alloy, gold-silver alloy, etc.), a conductive nitride (tantalum nitride, titanium nitride, etc.), or the like. Among these, the first region preferably contains a simple metal, an alloy, or a conductive nitride, and more preferably contains at least one selected from the group consisting of copper, cobalt, tungsten, tantalum, titanium, and ruthenium.

In the case where the second region is a region formed of an insulating material, the second region is formed of, for example, silicon-containing compounds such as silicon oxide, silicon nitride, silicon oxynitride, and silicide (for example, SiO₂, SiOC, Si₃N₄, SiNx, SiON, SiC, SiOCN, etc.), and metal oxides (for example, alumina, tantalum oxide, etc.). The second region preferably contains silicon oxide, silicon nitride, silicon oxynitride, silicide, or metal oxide.

In particular, in the case where the substrate to which the surface modification composition is coated has a region containing at least one selected from the group consisting of copper, cobalt, tungsten, tantalum, titanium, molybdenum, and ruthenium as the first region, and has a region containing silicon oxide, silicon nitride, silicon oxynitride, or metal oxide as the second region, it is suitable in that Compound (A) can be adsorbed highly selectively and densely to the first region among the first region and the second region.

The shape of the coating surface on the substrate is not particularly limited. The coating surface may be, for example, planar, arc-shaped, recessed, protruding, or the like. Moreover, in the case where the coating surface has the first region and the second region, the arrangement form of the first region and the second region is also not particularly limited. For example, the first region and the second region may be arranged in a predetermined direction on a plane in a state where the first region and the second region are adjacent to each other. Alternatively, multiple other regions may be arranged within the one region between the first region and the second region. Moreover, one of the first region and the second region may form the bottom surface of a hole or groove formed in the substrate, and the other may constitute the side surface thereof.

The substrate surface to which the film forming composition is coated may be subjected to a pretreatment, such as the plasma treatment using, for example, H₂, a mixed gas of N₂ and H₂, O₂ gas, or the like, the cleaning treatment of the substrate surface, a wet modification treatment, or the like.

(Coating method) Examples of methods for coating the surface modification composition include the spray method, the roll coating method, the spin coating method, the slit die coating method, the bar coating method, the inkjet method, and the like. Among these, it is preferable to coat the surface modification composition to the substrate surface according to the spin coating method, the slit die coating method, or the bar coating method. The film thickness of the coating film formed on the substrate can be appropriately set so that the thickness of the film eventually formed on the substrate becomes a desired thickness.

By coating the surface modification composition to the surface of the substrate through the coating process, a film (specifically a monomolecular film) by Compound (A) is formed on the first region. After coating the surface modification composition to the substrate surface, the solvent component in the surface modification composition may be removed through drying naturally, thereby forming a film on the first region. Moreover, a heat treatment for removing the solvent component from the surface modification composition coated to the substrate surface may be performed. The heat treatment can be performed by using a heating device such as an oven or hot plate. The heating temperature is, for example, 40° C. or higher, and may be 50° C. or higher. The heating time is, for example, 0.5 minutes to 60 minutes. Compound (A) has high adsorption ability to metal and is suitable in that it can form a film in the first region without performing a heat treatment and can simplify the manufacturing process. The thickness of the film formed on the substrate is, for example, several nm (for example, about 0.5 nm to 20 nm).

The selective modification method preferably further includes a process (hereinafter also referred to as “cleaning process”) of removing components derived from the surface modification composition on the second region by bringing the substrate surface into contact with a rinse solution after coating the surface modification composition through the coating process described above, thereby cleaning the substrate surface. Through the cleaning process, in the case where the components derived from the surface modification composition (more specifically, the composition itself, Compound (A), residual film formed by the composition, etc.) remain as residues on the second region, the residues can be removed from the second region. In this way, the region to be protected on the substrate surface can be covered more highly selectively by the film formed by Compound (A), and the substrate surface can be more highly selectively protected.

### Cleaning Process

As the rinse solution, an organic solvent can be preferably used. Examples of the organic solvent include propylene glycol monomethyl ether acetate, isopropanol, acetone, methyl ethyl ketone, methyl-n-propyl ketone, and mixed solvents of two or more of the above.

To remove components derived from the surface modification composition on the second region from the second region by using the rinse solution, the substrate surface after the coating process is brought into contact with the rinse solution. The method of bringing the substrate surface into contact with the rinse solution is not particularly limited, and for example, a shower method, a spray method, a dip (immersion) method, a puddle method, etc., can be applied. In bringing the substrate surface into contact with the rinse solution, for example, a treatment of supplying the rinse solution onto and making the rinse solution contact the substrate may be performed multiple times, or the rinse solution or the substrate may be shaken. The temperature of the rinse solution at the time of bringing the substrate surface into contact with the rinse solution is, for example, 5° C. to 50° C. The contact time is, for example, 5 seconds to 30 minutes. The amount of rinse solution used can be appropriately set in consideration of the contact method between the substrate surface and the rinse solution, etc. After bringing the substrate surface into contact with the rinse solution, the rinse solution on the substrate may be removed by using a spin coater or the like.

According to the method that includes the coating process described above and optionally includes the cleaning process, a substrate that has received the surface treatment using a composition containing Compound (A) and water can be obtained. That is, according to the disclosure, a method for manufacturing a surface-treated substrate, including a process of coating a composition to the substrate surface to selectively modify the substrate surface is provided.

With the method including the coating process described above, the substrate surface can receive surface-modification with high selectivity and high density through simple treatment.

For the substrate obtained by the coating process and the optionally included cleaning process, each treatment through the following processes (contact process, metal layer formation process, film removal process), for example, may be further performed.

### Contact Process

The contact process is a process of bringing alcohol, dilute acid, hydrogen peroxide water, ozone, plasma, ammonia, or ammonium fluoride salt aqueous solution into contact after forming a film on the first region through the coating process (preferably on the substrate surface after contact with the rinse solution through the cleaning process). In the manufacturing process of a semiconductor, etc., an oxide film layer may be formed on the contact surface (on the second region) with air on the substrate surface due to the substrate surface being exposed to air. Therefore, by providing such a contact process, the oxide film layer formed on the second region can be removed. Among the above, examples of dilute acids include dilute hydrochloric acid, dilute sulfuric acid, dilute citric acid, dilute oxalic acid, dilute maleic acid, dilute acetic acid, dilute isobutyric acid, dilute 2-ethylhexanoic acid, and the like.

### Metal Layer Formation Process

The metal layer formation process is a process of forming a metal layer on the second region after forming a film on the first region by the coating process (preferably after the contact with the rinse solution through the cleaning process, more preferably after the contact process). Among the substrate surface after the cleaning process, the first region is covered with a protective film (monomolecular film) formed by Compound (A). Therefore, at the time forming a metal layer by the metal layer formation process, the metal layer can be selectively formed on the second region among the first region and the second region. The method for forming the metal layer is not particularly limited, but from the viewpoint of performing pattern formation with high selectivity on fine regions, it is preferable to form a metal pattern through the chemical vapor deposition (CVD) method or the atomic layer deposition (ALD) method. The metal layer formed on the second region may be a barrier layer for separating the metal portion and the insulating portion or for suppressing the diffusion of metal from the metal portion. The thickness of the metal layer can be appropriately set according to the purpose of the substrate and the like, but is, for example, 1 nm to 30 nm.

### Film Removal Process

The film removal process is a process of removing the film formed on the first region after forming the metal layer on the second region through the metal layer formation process. The removal of the film can be performed by etching. Examples of the etching method include conventional methods such as reactive ion etching (RIE) and physical etching. Examples of reactive ion etching include chemical dry etching using CF₄, O₂ gas, and the like, utilizing differences in etching rate of respective layers; chemical wet etching (wet development) using liquid etching solutions such as organic solvents and hydrofluoric acid. Examples of physical etching include sputter etching and ion beam etching. Among these, reactive ion etching is preferable, and chemical dry etching or chemical wet etching is more preferable.

Examples of solvents used in chemical wet etching include acetic acid, a mixture of ammonia, hydrogen peroxide water, and water (APM), a mixture of sulfuric acid and hydrogen peroxide water (SPM), 2.38 mass % TMAH aqueous solution, dilute hydrofluoric acid, water, and the like.

By implementing the processes (coating process, cleaning process, contact process, metal layer formation process, and film removal process), a metal layer is selectively formed on the second region, and, for the first region, a substrate in a state where the surface of the first region (e.g., metal surface) is in an exposed state can be obtained. The obtained substrate may further receive various treatments such as a plating treatment. In the case where a plating treatment is performed, the plating method is not particularly limited, and conventional electroplating, electroless plating, hot-dip plating, vacuum plating, vapor phase plating, and the like can be adopted. In the case of application to a semiconductor manufacturing process, among the above, electroplating or electroless plating is preferable. After the plating treatment, a substrate surface planarization treatment (CMP treatment) and the like may be performed as necessary.

According to the disclosure described above, the following means are provided.

[Means 1] A method for selectively modifying a substrate surface includes: a process of coating a composition onto a surface of a substrate. The composition includes: Compound (A) having a carboxylate anion component and a monovalent organic group having 8 carbon atoms or more; and water.

[Means 2] In the method for selectively modifying the substrate surface according to [Means 1], the substrate includes a first region and a second region having a material different from the first region, and a film is formed on the first region by coating the composition on the surface of a substrate including the first region and the second region.

[Means 3] In the method for selectively modifying the substrate surface according to [Means 2], the first region is formed of a conductive material, and the second region is formed of an insulating material.

[Means 4] The method for selectively modifying the substrate surface according to [Means 2] or [Means 3], further includes a process of forming a metal layer on the second region after the film is formed on the first region.

[Means 5] The method for selectively modifying the substrate surface according to [Means 4] further includes a process of bringing alcohol, dilute acid, hydrogen peroxide water, ozone, plasma, ammonia, or ammonium fluoride salt aqueous solution into contact with the substrate surface after formation of the film on the first region and before formation of the metal layer.

[Means 6] The method for selectively modifying the substrate surface according to [Means 4] or

[Means 5] further includes a process of removing the film formed by the composition on the first region after formation of the metal layer.

[Means 7] The method for selectively modifying the substrate surface according to any one of [Means 4] to [Means 6] further includes a process of removing a component derived from the composition on the second region by bringing the surface of the substrate into contact with a rinse solution after coating of the composition and before formation of the metal layer.

[Means 8] In the method for selectively modifying the substrate surface according to any one of [Means 1] to [Means 7], the composition further contains a pH adjuster.

[Means 9] In the method for selectively modifying the substrate surface according to [Means 8], the pH adjuster is an organic acid having 8 carbon atoms or less, an organic base, or ammonia.

[Means 10] In the method for selectively modifying the substrate surface according to [Means 8] or [Means 9], the pH adjuster is a carboxy group-containing chain compound having 8 carbon atoms or less, a chain monoamine compound, or ammonia.

[Means 11] In the method for selectively modifying the substrate surface according to any one of [Means 1] to [Means 10], the monovalent organic group having 8 carbon atoms or more possessed by Compound (A) is a monovalent hydrocarbon group or halogenated hydrocarbon group.

[Means 12] In the method for selectively modifying the substrate surface according to any one of [Means 1] to [Means 11], the monovalent organic group having 8 carbon atoms or more possessed by Compound (A) is a monovalent chain hydrocarbon group.

[Means 13] In the method for selectively modifying a substrate surface according to any one of [Means 1] to [Means 12], Compound (A) has two or more of the carboxylate anion components.

[Means 14] In the method for selectively modifying the substrate surface according to any one of [Means 1] to [Means 13], a content of water is 10% by mass or more relative to a total amount of the composition.

[Means 15] In the method for manufacturing the substrate according to any one of [Means 1] to [Means 15], the composition further includes a cleaning component.

[Means 16] In the method for manufacturing the substrate according to [Means 15], the cleaning component is a fluorine compound.

[Means 17] In the method for selectively modifying the substrate surface according to any one of [Means 1] to [Means 16], the composition further includes an organic solvent, and a content of the organic solvent in the composition is 60% by mass or less relative to a total amount of the composition.

[Means 18] In the method for selectively modifying a substrate surface according to [Means 17], the organic solvent included in the composition is at least one selected from a group consisting of alcohols, ethers, ketones, sulfones, amides, cyclic amines, lactams, and esters.

[Means 19] A method for manufacturing a surface-treated substrate includes a process of coating a composition on a surface of the substrate to selectively modify the surface of the substrate. The composition contains Compound (A) having a carboxylate anion component and a monovalent organic group having 8 carbon atoms or more, and water.

[Means 20] A composition for selective modification of a substrate surface includes: Compound (A) having a carboxylate anion component and a monovalent organic group having 8 carbon atoms or more, and water.

[Means 21] In the composition according to [Means 20], Compound (A) has two or more of the carboxylate anion components.

[Means 22] In the composition according to [Means 20] or [Means 21], the monovalent organic group having 8 carbon atoms or more that Compound (A) has is a monovalent hydrocarbon group or halogenated hydrocarbon group.

[Means 23] The composition according to any one of [Means 20] to [Means 22] further includes a pH adjuster.

[Means 24] In the composition according to any one of [Means 20] to [Means 23], a content of water is 10% by mass or more relative to a total amount of the composition.

[Means 25] The composition according to any one of [Means 20] to [Means 24] further includes an organic solvent, and a content of the organic solvent is 60% by mass or less relative to a total amount of the composition.

### EXAMPLES

Hereinafter, the invention will be specifically described based on examples, but the invention is not limited to these examples. The measurement methods for the respective physical property values are shown below.

### 1. Preparation of Composition (Surface Modification Composition)

### Example 1

336.90 g of distilled water and 150.00 g of butoxyethanol were added to 0.20 g of octylsuccinic acid and stirred, then 0.05 g of maleic acid and 0.13 g of potassium hydroxide were added, and the pH was adjusted to 8.0, followed by filtration through a high-density polyethylene filter having pores of 0.45 μm to prepare a composition (SM-1) having a solid content concentration of Compound (A) of 1.0%.

### Examples 2 to 45 and Comparative Examples 1 to 5

Compositions (SM-2) to Composition (SM-45) and Compositions (SR-1) to Composition (SR-5) were respectively prepared by performing the same operations as in Example 1 above, except that the types and the blending amounts of respective components shown in Tables 1 and 2 were used.

The respective components used for preparing the surface modification composition are as follows

### Low Molecular Weight Compound

A-1; octylsuccinic acid
A-2; decylsuccinic acid
A-3; octadecylsuccinic acid
A-4; triacontanesuccinic acid
A-5; nonanoic acid
A-6; undecanoic acid
A-7; nonadecanoic acid
A-8; hentriacontanoic acid
A-9; 1-decenylsuccinic acid
A-10; 1-octadecenylsuccinic acid
A-11; 10,10,10-trifluorodecylsuccinic acid
A-12; 18,18,18-trifluorooctadecylsuccinic acid
A-13; sodium octadecylsuccinate
A-14; potassium octadecylsuccinate
A-15; ammonium octadecylsuccinate
A-16; tetramethylammonium octadecylsuccinate
A-17; tetrabutylammonium octadecylsuccinate
A-18; ethanolamine octadecylsuccinate
A-19; triethanolamine octadecylsuccinate
a-1; octadecane
a-2; benzotriazole
a-3; Kao Akypo RLM-45NV (manufactured by Kao Corporation)

### Solvent

SOL-1; butoxyethanol
SOL-2; triethylene glycol dimethyl ether
SOL-3; diethylene glycol monobutyl ether
SOL-4; sulfolane
SOL-5; dimethylformamide
SOL-6; dimethyl sulfoxide
SOL-7; isopropyl alcohol
SOL-8; 1,3-dimethyl-2-imidazolidinone

### pH Adjuster

Ada-1; maleic acid
Ada-2; malonic acid
Ada-3; citric acid
Ada-4; oxalic acid
Ada-5; acetic acid
Ada-6; phosphoric acid
Ada-7; sulfuric acid
Ada-8; nitric acid
Ada-9; boric acid
Ada-10; succinic acid
Ada-11; hydrochloric acid
Adb-1; potassium hydroxide
Adb-2; ammonia
Adb-3; 2-ethanolamine
Adb-4; diethanolamine
Adb-5; triethanolamine
Adb-6; propylamine
Adb-7; dibutylamine
Adb-8; tetramethylammonium hydroxide
Adb-9; tetraethylammonium hydroxide
Adb-10; tetrabutylammonium hydroxide

### Cleaning Component

Mol-1; hydrofluoric acid
Mol-2; ammonium fluoride
Mol-3; tetramethylammonium fluoride
Mol-4; hexafluorosilicic acid
Mol-5; hydrogen peroxide

TABLE 1

| | | Low Mw compound | | water | Organic solvent | | Other additive(s) | | | | | | |
|---|---|---|---|---|---|---|---|---|---|---|---|---|---|
| | Composition | | Content | Content | | Content | | Content | | Content | | Content | |
| | Name | Type | (mass %) | (mass %) | Type | (mass %) | Type | (mass %) | Type | (mass %) | Type | (mass %) | pH |
| Example 1 | SM-1 | A-1 | 0.10 | 69.9 | SOL-1 | 30.0 | Ada-1 | 0.002 | Adb-1 | 0.015 | — | — | 8.0 |
| Example 2 | SM-2 | A-2 | 0.10 | 69.9 | SOL-1 | 30.0 | Ada-2 | 0.002 | Adb-2 | 0.015 | — | — | 8.0 |
| Example 3 | SM-3 | A-3 | 0.10 | 69.9 | SOL-1 | 30.0 | Ada-3 | 0.001 | Adb-3 | 0.015 | — | — | 8.0 |
| Example 4 | SM-4 | A-4 | 0.10 | 69.9 | SOL-1 | 30.0 | Ada-4 | 0.002 | Adb-4 | 0.015 | — | — | 8.0 |
| Example 5 | SM-5 | A-5 | 0.10 | 69.9 | SOL-1 | 30.0 | Ada-5 | 0.003 | Adb-5 | 0.015 | — | — | 8.0 |
| Example 6 | SM-6 | A-6 | 0.10 | 69.9 | SOL-1 | 30.0 | Ada-6 | 0.001 | Adb-6 | 0.015 | — | — | 8.0 |
| Example 7 | SM-7 | A-7 | 0.10 | 69.9 | SOL-1 | 30.0 | Ada-7 | 0.002 | Adb-7 | 0.015 | — | — | 8.0 |
| Example 8 | SM-8 | A-8 | 0.10 | 69.9 | SOL-1 | 30.0 | Ada-8 | 0.003 | Adb-8 | 0.015 | — | — | 8.0 |
| Example 9 | SM-9 | A-9 | 0.10 | 69.9 | SOL-1 | 30.0 | Ada-9 | 0.001 | Adb-9 | 0.015 | — | — | 8.0 |
| Example 10 | SM-10 | A-10 | 0.10 | 69.9 | SOL-1 | 30.0 | Ada-10 | 0.002 | Adb-10 | 0.015 | — | — | 8.0 |
| Example 11 | SM-11 | A-11 | 0.10 | 69.9 | SOL-1 | 30.0 | Ada-3 | 0.001 | Adb-3 | 0.015 | — | — | 8.0 |
| Example 12 | SM-12 | A-12 | 0.10 | 69.9 | SOL-1 | 30.0 | Ada-3 | 0.001 | Adb-3 | 0.015 | — | — | 8.0 |
| Example 13 | SM-13 | A-13 | 0.10 | 69.9 | SOL-1 | 30.0 | Ada-3 | 0.001 | Adb-3 | 0.005 | — | — | 8.0 |
| Example 14 | SM-14 | A-14 | 0.10 | 69.9 | SOL-1 | 30.0 | Ada-3 | 0.001 | Adb-3 | 0.005 | — | — | 8.0 |
| Example 15 | SM-15 | A-15 | 0.10 | 69.9 | SOL-1 | 30.0 | Ada-3 | 0.001 | Adb-3 | 0.005 | — | — | 8.0 |
| Example 16 | SM-16 | A-16 | 0.10 | 69.9 | SOL-1 | 30.0 | Ada-3 | 0.001 | Adb-3 | 0.005 | — | — | 8.0 |
| Example 17 | SM-17 | A-17 | 0.10 | 69.9 | SOL-1 | 30.0 | Ada-3 | 0.001 | Adb-3 | 0.005 | — | — | 8.0 |
| Example 18 | SM-18 | A-18 | 0.10 | 69.9 | SOL-1 | 30.0 | Ada-3 | 0.001 | Adb-3 | 0.005 | — | — | 8.0 |
| Example 19 | SM-19 | A-19 | 0.10 | 69.9 | SOL-1 | 30.0 | Ada-3 | 0.001 | Adb-3 | 0.005 | — | — | 8.0 |
| Example 20 | SM-20 | A-3 | 1.00 | 68.9 | SOL-1 | 30.0 | Ada-3 | 0.001 | Adb-3 | 0.100 | — | — | 8.0 |
| Example 21 | SM-21 | A-3 | 0.50 | 69.4 | SOL-1 | 30.0 | Ada-3 | 0.001 | Adb-3 | 0.050 | — | — | 8.0 |
| Example 22 | SM-22 | A-3 | 0.02 | 69.9 | SOL-1 | 30.0 | Ada-3 | 0.001 | Adb-3 | 0.070 | — | — | 8.0 |
| Example 23 | SM-23 | A-3 | 0.01 | 70.0 | SOL-1 | 30.0 | Ada-3 | 0.001 | Adb-3 | 0.030 | — | — | 8.0 |
| Example 24 | SM-24 | A-3 | 0.10 | 69.9 | SOL-2 | 30.0 | Ada-3 | 0.001 | Adb-3 | 0.015 | — | — | 8.0 |
| Example 25 | SM-25 | A-3 | 0.10 | 69.9 | SOL-3 | 30.0 | Ada-3 | 0.001 | Adb-3 | 0.015 | — | — | 8.0 |

TABLE 2

| | Compo- | Low Mw compound | | water | Organic solvent | | Other additive(s) | | | | | | |
|---|---|---|---|---|---|---|---|---|---|---|---|---|---|
| | sition | | Content | Content | | Content | | Content | | Content | | Content | |
| | Name | Type | (mass %) | (mass %) | Type | (mass %) | Type | (mass %) | Type | (mass %) | Type | (mass %) | pH |
| Example 26 | SM-26 | A-3 | 0.10 | 69.9 | SOL-4 | 30.0 | Ada-3 | 0.001 | Adb-3 | 0.015 | — | — | 8.0 |
| Example 27 | SM-27 | A-3 | 0.10 | 69.9 | SOL-5 | 30.0 | Ada-3 | 0.001 | Adb-3 | 0.015 | — | — | 8.0 |
| Example 28 | SM-28 | A-3 | 0.10 | 69.9 | SOL-6 | 30.0 | Ada-3 | 0.001 | Adb-3 | 0.015 | — | — | 8.0 |
| Example 29 | SM-29 | A-3 | 0.10 | 69.9 | SOL-7 | 30.0 | Ada-3 | 0.001 | Adb-3 | 0.015 | — | — | 8.0 |
| Example 30 | SM-30 | A-3 | 0.10 | 69.9 | SOL-8 | 30.0 | Ada-3 | 0.001 | Adb-3 | 0.015 | — | — | 8.0 |
| Example 31 | SM-31 | A-3 | 0.10 | 99.9 | — | — | Ada-3 | 0.001 | Adb-3 | 0.015 | — | — | 8.0 |
| Example 32 | SM-32 | A-3 | 0.10 | 94.9 | SOL-1 | 5.0 | Ada-3 | 0.001 | Adb-3 | 0.015 | — | — | 8.0 |
| Example 33 | SM-33 | A-3 | 0.10 | 54.9 | SOL-1 | 45.0 | Ada-3 | 0.001 | Adb-3 | 0.015 | — | — | 8.0 |
| Example 34 | SM-34 | A-3 | 0.10 | 29.9 | SOL-1 | 70.0 | Ada-3 | 0.001 | Adb-3 | 0.015 | — | — | 8.0 |
| Example 35 | SM-35 | A-3 | 0.10 | 69.9 | SOL-1 | 30.0 | Ada-3 | 0.001 | Adb-3 | 0.002 | — | — | 5.0 |
| Example 36 | SM-36 | A-3 | 0.10 | 69.9 | SOL-1 | 30.0 | Ada-3 | 0.001 | Adb-3 | 0.010 | — | — | 7.0 |
| Example 37 | SM-37 | A-3 | 0.10 | 69.9 | SOL-1 | 30.0 | Ada-3 | 0.001 | Adb-3 | 0.030 | — | — | 9.0 |
| Example 38 | SM-38 | A-3 | 0.10 | 69.8 | SOL-1 | 30.0 | Ada-3 | 0.001 | Adb-3 | 0.060 | — | — | 11.0 |
| Example 39 | SM-39 | A-3 | 0.10 | 69.9 | SOL-1 | 30.0 | Ada-3 | 0.001 | Adb-3 | 0.025 | MOL-1 | 0.010 | 8.0 |
| Example 40 | SM-40 | A-3 | 0.10 | 69.8 | SOL-1 | 30.0 | Ada-3 | 0.001 | Adb-3 | 0.050 | MOL-2 | 0.100 | 8.0 |
| Example 41 | SM-41 | A-3 | 0.10 | 69.8 | SOL-1 | 30.0 | — | 0.001 | Adb-3 | 0.100 | MOL-3 | 1.000 | 8.0 |
| Example 42 | SM-42 | A-3 | 0.10 | 69.4 | SOL-1 | 30.0 | Ada-3 | 0.001 | Adb-3 | 0.500 | MOL-4 | 5.000 | 8.0 |
| Example 43 | SM-43 | A-3 | 0.10 | 29.2 | SOL-1 | 70.0 | Ada-3 | 0.001 | Adb-3 | 0.700 | — | — | 9.5 |
| Example 44 | SM-44 | A-3 | 0.10 | 95.8 | — | — | — | — | Adb-2 | 4.140 | MOL-5 | 4.430 | 8.0 |
| Example 45 | SM-45 | A-3 | 0.10 | 94.8 | — | — | Ada-11 | 5.140 | — | — | MOL-5 | 4.430 | 8.0 |
| Comparative | SR-1 | — | — | 70.0 | SOL-1 | 30.0 | Ada-3 | 0.001 | Adb-3 | 0.005 | — | — | 8.0 |
| Example 1 | | | | | | | | | | | | | |
| Comparative | SR-2 | a-1 | 0.10 | 69.9 | SOL-1 | 30.0 | Ada-3 | 0.001 | Adb-3 | 0.005 | — | — | 8.0 |
| Example 2 | | | | | | | | | | | | | |
| Comparative | SR-3 | — | — | 69.8 | SOL-1 | 30.0 | Ada-4 | 0.100 | Adb-3 | 0.080 | — | — | 8.0 |
| Example 3 | | | | | | | | | | | | | |
| Comparative | SR-4 | a-2 | 0.10 | 69.8 | SOL-1 | 30.0 | Ada-3 | 0.001 | Adb-3 | 0.050 | — | — | 8.0 |
| Example 4 | | | | | | | | | | | | | |
| Comparative | SR-5 | a-3 | 0.10 | 69.9 | SOL-1 | 30.0 | Ada-3 | 0.001 | Adb-3 | 0.005 | — | — | 8.0 |
| Example 5 | | | | | | | | | | | | | |

### 2. Evaluation

By using Composition (SM-1) to Composition (SM-45) and Composition (SR-1) to Composition (SR-5) prepared in the above 1, the evaluation shown below was performed. The results are shown in Table 2.

### <Evaluation of Solubility>

The solubility of each composition obtained in 1 above was evaluated by visual observation.

### (Evaluation Criteria)

A (good): Transparent
B (acceptable): Either turbidity or undissolved residue was confirmed
C (poor): Both turbidity and undissolved residue were confirmed

### <Evaluation of Storage Stability>

10 g of each composition prepared in 1 above was placed in a vial and stored at 50° C. for 2 weeks. The amount of change in viscosity before and after storage was expressed as Δη, and storage stability was evaluated by measuring the change amount Δη. The smaller the viscosity change amount Δη, the more it can be coated under the same coating conditions without daily variation, and the more favorable the storage stability can be evaluated as.

### (Evaluation Criteria)

A (good): Δη being less than 1 Pa·s
B (acceptable): Δη being 1 Pa·s or more and less than 3 Pa·s
C (poor): Δη being 3 Pa s or more

### <Evaluation of Hydrophobization Property (Evaluation of Selective Modification Property)>

A wafer piece with a 20 nm copper film, a wafer piece with a 20 nm aluminum oxide film, a wafer piece with a 30 nm tantalum nitride film, a wafer piece with a 20 nm carbon-doped tungsten film (WdC), a wafer piece with a 1000 nm silicon oxide film (p-TEOS film), and a wafer substrate with a 500 nm low dielectric silicon oxide film (LowK) were cut into 3 cm×3 cm pieces and immersed into the respective compositions prepared in 1 above for 1 minute respectively. Thereafter, the wafer pieces were taken out and cleaned with water and isopropyl alcohol to obtain treated articles. By dropping water onto the treated articles, the static contact angles of the film formation surfaces were measured using a contact angle meter (“Drop master DM-501” manufactured by Kyowa Interface Science Co., Ltd.).

### (Evaluation Criteria for Copper Film)

A substrate in which the static contact angle after surface treatment with the composition is significantly increased relative to the static contact angle of the substrate before surface treatment with the composition can be said as being selectively modified by the low molecular compound in the composition and that a film is formed on the substrate. Since it is desirable for the copper film (Cu) to be in a modified state (i.e., a state covered by the film), the evaluation was performed according to the following criteria.
A (good): Contact angle is 90 degrees or more. A film is formed with high density on the substrate and is suitable for practical use, therefore judged as “good”.
B (acceptable): Contact angle is 70 degrees or more and less than 90 degrees. A film is formed on the substrate and is suitable for practical use, therefore judged as “acceptable”.
C (poor): Contact angle is less than 70 degrees. No film is formed on the substrate, or a film is formed with low density and cannot be put into practical use, therefore judged as “poor”.

### (Evaluation Criteria for Aluminum Oxide Film, Tantalum Nitride Film, Carbon-Doped Tungsten Film, Silicon Oxide Film, Low Dielectric Silicon Oxide)

Since it is desirable for the aluminum oxide film (AlOx), tantalum nitride film (TiN), carbon-doped tungsten film (WdC), silicon oxide film (TEOS), and low dielectric silicon oxide film (Low K) to be in a non-modified state (i.e., a state not covered by a film), evaluation was performed according to the following criteria.
A (good): Contact angle is less than 40 degrees. No film is formed on the substrate and is suitable for practical use, therefore judged as “good”.
B (acceptable): Contact angle is 40 degrees or more and less than 70 degrees. A film is partially formed on the substrate and is suitable for practical use, therefore judged as “acceptable”.
C (poor): Contact angle is 70 degrees or more. A film is uniformly formed on the substrate and cannot be put to practical use, therefore judged as “poor”.

In the case where various substrates are evaluated as “good” or “acceptable” (i.e., there is no “poor” evaluation), it can be said that the substrate is selectively surface-modified.

### <Evaluation of Metal Corrosion Resistance (Evaluation According to Etching Rate)>

Various substrates used for hydrophobicity evaluation were cut to 3.5 cm×3.5 cm and immersed in each composition prepared in 1 above for 10 minutes respectively. Thereafter, the wafer pieces were extracted and cleaned with water and isopropyl alcohol to obtain treated articles. The film thicknesses of the treated articles were measured using a fluorescent X-ray analyzer (manufactured by Rigaku Corporation, model “AZX400”) and a spectroscopic ellipsometer (manufactured by Semilab Semiconductor Physics Laboratory Co. Ltd., model “SE-2000”), and the etching rate weas calculated from the film thickness before and after immersion in each composition.

### (Evaluation Criteria)

A (good): Etching rate is less than 0.1 nm/min. Judged as “good” because excessive corrosion can be suppressed.
B (acceptable): Etching rate is 0.1 nm/min or more and less than 0.5 nm/min. Judged as “acceptable” because corrosion can be suppressed and practical use is possible.
C (poor): Etching rate is 0.5 nm/min or more. Judged as “poor” because corrosion is significant and practical use is not possible.

### <<Evaluation of Coatability>>

Using an 8-inch copper substrate, the coatability of each composition was evaluated. The substrate was cut to 3 cm×3 cm, and each composition prepared in 1 above was spin-coated using a spin coater (“MS-B300” from Mikasa Co., Ltd.) under the condition of 1,500 rpm for 20 seconds (coating process). Next, the substrate after coating was baked at 150° C. for 180 seconds. Thereafter, the substrate was cleaned using propylene glycol monomethyl ether acetate as a rinse solution (cleaning process). In the cleaning process, in the case where components in the composition were not adsorbed onto the substrate surface, the components in the composition remaining on the substrate were removed by the rinse solution, and no film was formed on the substrate. In the evaluation of coatability, the coated surface of the substrate was observed with an optical microscope, and the presence or absence of voids and film breakage on the film surface was verified and evaluated.

### (Evaluation Criteria)

A (good): No voids and film breakage.
B (acceptable): No film breakage but voids are present.
C (poor): Both voids and film breakage are present.

### <Evaluation of Dry Etch Residue Removal Performance (Evaluation by Etching Rate)>

Using a reactive ion etching apparatus (RIE-10NR), a dry etching treatment was performed on a LowK film substrate to obtain a treated article. The obtained treated article was cut to 3.5 cm×3.5 cm and immersed in each composition prepared in 1 above for 1 minute respectively.

Thereafter, the wafer piece (treated article) was extracted and cleaned with water and isopropyl alcohol. By X-ray photoelectron spectroscopy (manufactured by ULVAC, model “Quantum2000”), the F component on the surface of the treated article after cleaning was quantified, and the quantified value of the F component in the substrate not immersed in each composition was used as a reference value, and the ratio of the quantified value of the F component in the surface-treated substrate was calculated as cleaning efficiency (%).

### (Evaluation Criteria)

A (good): Cleaning efficiency is 98% or more.
B (acceptable): Cleaning efficiency is less than 98% and 90% or more.
C (poor): Cleaning efficiency is less than 90%.

### (Dry Etching Conditions)

Gas flow rate: Ar/C₄F₈/N₂=100/50/33 sccm
Plasma power: 170 W/40 MHz (high frequency), 80 W/13 MHz (low frequency)
Pressure: 50 mTorr
Prescribed time: 100 seconds

### <Evaluation of Metal Oxide Blocking Performance (Evaluation of ALD Resistance)>

For substrates (surface-treated substrates) having copper film-attached wafer pieces surface-coated with each composition prepared in 1, ALD processing was performed under the following conditions using Cambridge Nanotech FIJI at Stanford University to obtain ALD treated articles of the surface-treated substrates. As a control, copper film-attached wafer pieces (untreated substrates) that had not been surface-treated with each composition were used, and ALD was performed in the same manner as the surface-treated substrates to obtain ALD treated articles of the untreated substrates. Ti components on the substrate surfaces of the ALD treated articles (surface-treated substrates and untreated substrates) were quantified by X-ray photoelectron spectroscopy (manufactured by ULVAC, Inc., model “Quantum2000”). The ratio of the quantified value of Ti component in the surface-treated substrate to the reference value of the quantified value of Ti component in the untreated substrate was calculated as the blocking rate (%). The larger the blocking rate value, the more the film formed on the substrate by the composition is formed by high-density adsorption of components in the composition (low molecular compounds in Tables 1 and 2) on the substrate surface, and the substrate can be said to have high blocking performance against metal oxide formation by ALD.

### (Evaluation Criteria)

A (good): blocking rate is 98% or more.
B (acceptable): blocking rate is less than 98% and 90% or more.
C (poor): blocking rate is less than 90%.

### (ALD Conditions)

Film type: ALD Al₂O₃
Stage temperature: 200° C.
Prescribed time: 0.3 seconds (trimethyl aluminum)/15 seconds (purge)/0.06 seconds (water)/23 seconds (purge)

### <Measurement of Metal Content>

Each composition prepared in 1 above was diluted 20-fold with diethylene glycol butyl ether/ultrapure water-80/20 (parts by mass), and the contents of sodium, potassium and calcium were measured by using an ICP mass spectrometer (manufactured by Perkin Elmer, model “NexION 5000”).

### (Evaluation Criteria)

A (good): The total content of sodium, potassium and calcium is less than 1 ppm. Judged as “good” particularly for practical use.
B (acceptable): The total content of sodium, potassium and calcium is 1 ppm or more and less than 500 ppm. Judged as “acceptable” for practical use.
C (poor): The total content of sodium, potassium and calcium is 500 ppm or more. Judged as “poor” because it cannot be used for practical purposes.

### <Evaluation of Film Thickness>

Various substrates used for hydrophobicity evaluation were cut to 1.0 cm×1.0 cm and immersed in each composition prepared in 1 above for 1 minute respectively. Thereafter, the wafer pieces were extracted and cleaned with water and isopropyl alcohol. Using a focused ion beam processing apparatus (manufactured by Japan FEI Co., Ltd., model “Helios650”), a treated article was obtained by carrying a hafnium oxide protective layer and then being thinned. The obtained treated article was observed by using a transmission electron microscope (manufactured by Japan FEI Co., Ltd., model “Talos F200X”), and the thickness of the film of the treated article was measured from annular dark field images.

### (Evaluation Criteria)

A (good): The film thickness is 0.5 nm or more and less than 2.0 nm.
B (acceptable): The film thickness is 2.0 nm or more and less than 25.0 nm.
C (poor): The film thickness is 25.0 nm or more.

TABLE 3

| | | | | | Hydrophobicity (selective | | | | | |
|---|---|---|---|---|---|---|---|---|---|---|
| | | | | Storage | modification properties) | | | | | |
| | Composition | Solubility | Coatability | stability | Cu | AlOx | TiN | WdC | TEOS | Low K |
| Example 1 | SM-1 | A | B | A | B | A | A | A | A | A |
| Example 2 | SM-2 | A | A | A | A | A | A | A | A | A |
| Example 3 | SM-3 | A | A | A | A | A | A | A | A | A |
| Example 4 | SM-4 | A | A | A | A | A | A | A | B | B |
| Example 5 | SM-5 | A | B | A | B | A | A | A | A | A |
| Example 6 | SM-6 | A | B | A | B | A | A | A | A | A |
| Example 7 | SM-7 | A | B | A | B | A | A | A | A | A |
| Example 8 | SM-8 | B | A | A | B | A | A | A | B | B |
| Example 9 | SM-9 | A | A | A | A | A | A | A | A | A |
| Example 10 | SM-10 | A | A | A | A | A | A | A | A | A |
| Example 11 | SM-11 | B | B | A | B | A | A | A | A | A |
| Example 12 | SM-12 | B | B | A | B | A | A | A | A | A |
| Example 13 | SM-13 | A | B | A | B | A | A | A | A | A |
| Example 14 | SM-14 | A | B | A | B | A | A | A | A | A |
| Example 15 | SM-15 | A | A | A | A | A | A | A | A | A |
| Example 16 | SM-16 | A | A | A | A | A | A | A | A | A |
| Example 17 | SM-17 | A | A | A | A | A | A | A | A | A |
| Example 18 | SM-18 | A | A | A | A | A | A | A | A | A |
| Example 19 | SM-19 | A | A | A | A | A | A | A | A | A |
| Example 20 | SM-20 | A | A | A | A | A | A | A | B | B |
| Example 21 | SM-21 | A | A | A | A | A | A | A | A | A |
| Example 22 | SM-22 | A | A | A | A | A | A | A | A | A |
| Example 23 | SM-23 | A | B | A | B | A | A | A | A | A |
| Example 24 | SM-24 | A | A | A | A | A | A | A | A | A |
| Example 25 | SM-25 | A | A | A | A | A | A | A | A | A |

| | | | | | | | | | Residue | |
|---|---|---|---|---|---|---|---|---|---|---|
| | Metal corrosion resistance | | | | | | Cu/ALD | Metal | removability | Film |
| | Cu | AlOx | TaN | WdC | TEOS | Low K | resistance | content | Low K | thickness |
| Example 1 | B | A | A | A | A | A | B | B | B | A |
| Example 2 | A | A | A | A | A | A | A | A | B | A |
| Example 3 | A | A | A | A | A | A | A | A | B | A |
| Example 4 | A | A | A | A | A | A | A | A | B | B |
| Example 5 | B | A | A | A | A | A | B | A | B | A |
| Example 6 | B | A | A | A | A | A | B | A | B | A |
| Example 7 | B | A | A | A | A | A | B | A | B | A |
| Example 8 | B | A | A | A | A | A | B | A | B | B |
| Example 9 | A | A | A | A | A | A | A | A | B | A |
| Example 10 | A | A | A | A | A | A | A | A | B | A |
| Example 11 | A | A | A | A | A | A | A | A | B | A |
| Example 12 | A | A | A | A | A | A | A | A | B | A |
| Example 13 | B | A | A | A | A | A | B | B | B | A |
| Example 14 | B | A | A | A | A | A | B | B | B | A |
| Example 15 | A | A | A | A | A | A | A | A | B | A |
| Example 16 | A | A | A | A | A | A | A | A | B | A |
| Example 17 | A | A | A | A | A | A | A | A | B | A |
| Example 18 | A | A | A | A | A | A | A | A | B | A |
| Example 19 | A | A | A | A | A | A | A | A | B | A |
| Example 20 | A | A | A | A | A | A | A | A | B | A |
| Example 21 | A | A | A | A | A | A | A | A | B | A |
| Example 22 | A | A | A | A | A | A | A | A | B | A |
| Example 23 | B | A | A | A | A | A | B | A | B | A |
| Example 24 | A | A | A | A | A | A | A | A | B | A |
| Example 25 | A | A | A | A | A | A | A | A | B | A |

TABLE 4

| | | | | | Hydrophobicity (selective | | | | | |
|---|---|---|---|---|---|---|---|---|---|---|
| | | | | Storage | modification properties) | | | | | |
| | Composition | Solubility | Coatability | stability | Cu | AlOx | TiN | WdC | TEOS | Low K |
| Example 26 | SM-26 | A | A | A | A | A | A | A | A | A |
| Example 27 | SM-27 | A | A | A | A | A | A | A | A | A |
| Example 28 | SM-28 | A | A | A | A | A | A | A | A | A |
| Example 29 | SM-29 | A | A | A | A | A | A | A | A | A |
| Example 30 | SM-30 | A | A | A | A | A | A | A | A | A |
| Example 31 | SM-31 | A | B | A | A | A | A | A | A | A |
| Example 32 | SM-32 | A | A | A | A | A | A | A | A | A |
| Example 33 | SM-33 | A | A | A | A | A | A | A | A | A |
| Example 34 | SM-34 | A | B | A | A | A | A | A | A | A |
| Example 35 | SM-35 | A | A | A | A | A | A | A | A | A |
| Example 36 | SM-36 | A | A | A | A | A | A | A | A | A |
| Example 37 | SM-37 | A | A | A | A | A | A | A | A | A |
| Example 38 | SM-38 | A | A | A | A | A | A | A | A | A |
| Example 39 | SM-39 | A | A | A | A | A | A | A | A | A |
| Example 40 | SM-40 | A | A | A | A | A | A | A | A | A |
| Example 41 | SM-41 | A | A | A | A | A | A | A | A | A |
| Example 42 | SM-42 | A | A | A | A | A | A | A | A | A |
| Example 43 | SM-43 | A | A | A | B | A | A | A | A | A |
| Example 44 | SM-44 | A | A | A | B | A | A | A | A | A |
| Example 45 | SM-45 | A | A | A | B | A | A | A | A | A |
| Comparative | SR-1 | A | C | A | C | A | A | A | A | A |
| Example 1 | | | | | | | | | | |
| Comparative | SR-2 | B | C | A | C | A | A | A | A | A |
| Example 2 | | | | | | | | | | |
| Comparative | SR-3 | A | C | A | C | A | A | A | A | A |
| Example 3 | | | | | | | | | | |
| Comparative | SR-4 | A | B | A | B | A | A | A | A | A |
| Example 4 | | | | | | | | | | |
| Comparative | SR-5 | A | C | A | C | A | A | A | A | A |
| Example 5 | | | | | | | | | | |

| | | | | | | | | | Residue | |
|---|---|---|---|---|---|---|---|---|---|---|
| | Metal corrosion resistance | | | | | | Cu/ALD | Metal | removability | Film |
| | Cu | AlOx | TaN | WdC | TEOS | Low K | resistance | content | Low K | thickness |
| Example 26 | A | A | A | A | A | A | A | A | B | A |
| Example 27 | A | A | A | A | A | A | A | A | B | A |
| Example 28 | A | A | A | A | A | A | A | A | B | A |
| Example 29 | A | A | A | A | A | A | A | A | B | A |
| Example 30 | A | A | A | A | A | A | A | A | B | A |
| Example 31 | A | A | A | A | A | A | A | A | B | A |
| Example 32 | A | A | A | A | A | A | A | A | B | A |
| Example 33 | A | A | A | A | A | A | A | A | B | A |
| Example 34 | B | A | A | A | A | A | B | A | B | A |
| Example 35 | A | A | A | A | A | A | A | A | B | A |
| Example 36 | A | A | A | A | A | A | A | A | B | A |
| Example 37 | A | A | A | A | A | A | A | A | B | A |
| Example 38 | A | A | A | A | A | A | A | A | B | A |
| Example 39 | A | A | A | A | A | A | A | A | A | A |
| Example 40 | A | A | A | A | A | A | A | A | A | A |
| Example 41 | A | A | A | A | A | A | A | A | A | A |
| Example 42 | A | A | A | A | A | A | A | A | A | A |
| Example 43 | B | A | A | A | A | A | B | A | B | A |
| Example 44 | B | A | B | B | A | A | B | A | B | A |
| Example 45 | B | A | B | B | A | A | B | A | B | A |
| Comparative | C | A | A | A | A | A | C | A | B | C |
| Example 1 | | | | | | | | | | |
| Comparative | C | A | A | A | A | A | C | A | B | C |
| Example 2 | | | | | | | | | | |
| Comparative | C | A | A | A | A | A | C | A | B | C |
| Example 3 | | | | | | | | | | |
| Comparative | B | A | A | A | A | A | C | A | B | C |
| Example 4 | | | | | | | | | | |
| Comparative | C | A | A | A | A | A | C | C | B | B |
| Example 5 | | | | | | | | | | |

As can be seen from the above results, the surface modification compositions of Examples 1 to 45, which used Compound (A) as the film forming material and contain water, showed good or acceptable evaluation results for solubility in water, coatability, and storage stability. In addition, by using the compositions of Examples 1 to 45, films can be formed on metal surfaces with high selectivity and high density. Furthermore, the films formed by the compositions of Examples 1 to 45 showed good metal corrosion resistance. In addition, Examples 3 and 15 to 19, in which the carboxylate anion component of Compound (A) as the film forming material forms a carboxy group with a hydrogen ion or forms a salt with an organic cation, exhibited lower metal contents in the composition than Examples 13 and 14, in which salts were formed with metal cations, and also showed more favorable coatability, selective modification property, metal corrosion resistance, and ALD resistance. From the results, it can be said that in the case where the carboxylate anion component in Compound (A) forms a carboxy group with a hydrogen ion or forms a salt with an organic cation, the coatability of the composition can be more favorable, and films with higher selectivity and higher density can be formed. In addition, Examples 39 to 42, in which cleaning components were blended in the compositions, showed favorable residue removal performance for LowK film substrates after dry etching.

Comparatively, the composition of Comparative Example 1, which used only an organic solvent as the solvent, showed results inferior to the Examples in the performance of coatability, selective modification property, ALD resistance, and film thickness, respectively. In addition, the composition of Comparative Example 2, which used octadecane in place of Compound (A), exhibited poor coatability, and all evaluations of selective modification property of metal surfaces, metal corrosion resistance, ALD resistance, and film thickness were poor. In addition, the composition of Comparative Example 3, which did not contain Compound (A), had poor coatability, and all evaluations of selective modification property of metal surfaces, metal corrosion resistance, ALD resistance, and film thickness were poor. In addition, the composition of Comparative Example 4, which used benzotriazole in place of Compound (A), showed poor evaluation for ALD resistance and film thickness. In addition, in Comparative Example 5, which used a commercially available surfactant in place of Compound (A), not only was the ALD resistance poor, but the metal content was also high.

1. A method for selectively modifying a substrate surface, the method comprising: a process of coating a composition onto a surface of a substrate, wherein the composition comprises: Compound (A) having a carboxylate anion component and a monovalent organic group having 8 carbon atoms or more; and water.

2. The method for selectively modifying the substrate surface according to claim 1, wherein the substrate comprises a first region and a second region having a material different from the first region, and a film is formed on the first region by coating the composition on a surface of the substrate comprising the first region and the second region.

3. The method for selectively modifying the substrate surface according to claim 2, wherein the first region is formed of a conductive material, and
the second region is formed of an insulating material.

4. The method for selectively modifying the substrate surface according to claim 2, further comprising: a process of forming a metal layer on the second region after the film is formed on the first region.

5. The method for selectively modifying the substrate surface according to claim 4, further comprising: a process of bringing alcohol, dilute acid, hydrogen peroxide water, ozone, plasma, ammonia, or ammonium fluoride salt aqueous solution into contact with the surface of the substrate after formation of the film on the first region and before formation of the metal layer.

6. The method for selectively modifying the substrate surface according to claim 4, further comprising: a process of removing the film formed by the composition on the first region after formation of the metal layer.

7. The method for selectively modifying the substrate surface according to claim 4, further comprising: a process of removing a component derived from the composition on the second region by bringing the surface of the substrate into contact with a rinse solution after coating of the composition and before formation of the metal layer.

8. The method for selectively modifying the substrate surface according to claim 1, wherein the composition further comprises a pH adjuster.

9. The method for selectively modifying the substrate surface according to claim 8, wherein the pH adjuster is an organic acid having 8 carbon atoms or less, an organic base, or ammonia.

10. The method for selectively modifying the substrate surface according to claim 8, wherein the pH adjuster is a carboxy group-containing chain compound having 8 carbon atoms or less, a chain monoamine compound, or ammonia.

11. The method for selectively modifying the substrate surface according to claim 1, wherein the monovalent organic group having 8 carbon atoms or more possessed by Compound (A) is a monovalent hydrocarbon group or halogenated hydrocarbon group.

12. (canceled)

13. The method for selectively modifying the substrate surface according to claim 1, wherein Compound (A) has two or more of the carboxylate anion components.

14. (canceled)

15. The method for selectively modifying the substrate surface according to claim 1, wherein the composition further comprises a cleaning component.

16. The method for selectively modifying the substrate surface according to claim 15, wherein the cleaning component is a fluorine compound.

17. The method for selectively modifying the substrate surface according to claim 1, wherein:
the composition further comprises an organic solvent, and
a content of the organic solvent in the composition is 60% by mass or less relative to a total amount of the composition.

18. The method for selectively modifying the substrate surface according to claim 17, wherein the organic solvent comprised in the composition is at least one selected from a group consisting of alcohols, ethers, ketones, sulfones, amides, cyclic amines, lactams, and esters.

19. (canceled)

20. A composition for selectively modifying a substrate surface, the composition comprising:
Compound (A), having a carboxylate anion component and a monovalent organic group having 8 carbon atoms or more; and
water,
wherein Compound (A) has two or more of the carboxylate anion components, and
the monovalent organic group having 8 carbon atoms or more that Compound (A) has is a monovalent hydrocarbon group or halogenated hydrocarbon group.

21. (canceled)

22. (canceled)

23. The composition according to claim 20, further comprising a pH adjuster.

24. The composition according to claim 20, wherein a content of water is 10% by mass or more relative to a total amount of the composition.

25. The composition according to claim 20, further comprising: an organic solvent, wherein a content of the organic solvent is 60% by mass or less relative to a total amount of the composition.
